(19) United States
(12) Patent Application Publication
(10) Pub. No.: US 2026/0269638 A1
(43) Pub. Date: Sep. 10, 2026

(54) SECONDARY BATTERY CHARGING AND DISCHARGING APPARATUS INTEGRATED WITH POWER SUPPLY UNIT

(71) Applicant: WONIK PNE CO., LTD., Suwon-si (KR)

(72) Inventors: Jaebong KANG, Suwon-si (KR); Chungil NAM, Suwon-si (KR)

(73) Assignee: WONIK PNE CO., LTD., Suwon-si (KR)

(21) Appl. No.: 19/556,475

(22) Filed: Mar. 4, 2026

(30) Foreign Application Priority Data
Mar. 5, 2025 (KR) 10-2025-0027830

(51) Int. Cl. H02J 7/70; G01R 31/385; H01M 4/04; H02J 7/00

(52) U.S. Cl. CPC H02J 7/70; G01R 31/385; H01M 4/0447; H02J 7/875

(57) ABSTRACT

Disclosed is a secondary battery charging and discharging apparatus integrated with a power supply unit, the secondary battery charging and discharging apparatus configured to perform charging and discharging for secondary battery activation or testing. The secondary battery charging and discharging apparatus integrated with a power supply unit according to the present disclosure includes: a jig unit configured to accommodate a plurality of secondary batteries; a rail unit disposed on the jig unit; and a power supply unit provided with a power module configured to charge and discharge the secondary batteries and a charging and discharging probe electrically connected to the power module, wherein the power supply unit is connected to the jig unit through the rail unit and is insertable into and withdrawable from the jig unit in a sliding manner.

### BACKGROUND

### 1. Technical Field

The present disclosure relates to a secondary battery charging and discharging apparatus, and more particularly, to a secondary battery charging and discharging apparatus integrated with a power supply unit in which a power supply unit configured to perform a power conversion function for charging and discharging a secondary battery is integrally configured with a jig unit configured to seat and secure the secondary battery, wherein the power supply unit is inserted into and withdrawn from the jig unit in a sliding manner.

### 2. Related Art

A secondary battery manufacturing process includes a charging and discharging process. The charging and discharging process is a key operation that determines performance and lifespan of a battery and plays an important role in promoting initial activation of the battery and making adjustment for optimal performance of the battery. The charging and discharging process is generally referred to as a formation process, and focuses on optimizing an active material reaction within a cell and forming a stable structure.

In particular, in a high-performance battery such as a lithium-ion battery, a solid electrolyte interphase (SEI) layer is formed through the charging and discharging process. The SEI layer is essential for protecting a surface of an electrode, suppressing decomposition of an electrolyte, and ensuring long-term stability of the battery. Quality of the SEI layer directly affects the initial capacity and charging and discharging efficiency of the battery. Accordingly, the charging and discharging process serves as criteria for evaluating initial performance of the secondary battery and determining whether the secondary battery is defective.

Conditions of the charging and discharging process have a significant influence on the performance and lifespan of the battery, and thus should be strictly managed. For example, heat generated during charging and discharging may affect the rate and uniformity of chemical reactions within the cell, and thus temperature during the process is strictly controlled. In addition, the magnitude of current and voltage used during charging and discharging, as well as a rate of charging and discharging should be optimized in accordance with characteristics and intended use of each battery.

Failure to manage the conditions may result in degraded performance, shortened lifespan, and even a safety issue of the battery. In particular, improper management of conditions of temperature and current may result in an excessive increase in internal heat generation, thus posing a risk of cell damage or thermal runaway. Accordingly, a real-time monitoring and control system within the process is essential to ensuring the safety and reliability of the battery.

A charging and discharging apparatus used in the secondary battery manufacturing process is designed to be suitable for mass production and has a function of simultaneously processing a plurality of cells (secondary batteries). Such equipment records and analyzes charging and discharging data of the cells in real time to assess quality of each of the cells. A data collection and analysis system measures capacity, voltage, internal resistance, or the like of each of the cells, and supports automatic selection of a cell that does not meet criteria.

However, a conventional charging and discharging apparatus used in a secondary battery manufacturing process has a structure in which a power supply unit configured to perform power conversion for charging and discharging a secondary battery includes a charging and discharging probe such that the power supply unit is separated from a jig unit on which the secondary battery is seated and secured, and is electrically connected to the jig unit through a separate cable. This structure requires a separate space for disposing the power supply unit, and increases an overall installation footprint of the equipment.

In addition, due to a plurality of cables configured to connect the power supply unit and the jig unit, maintainability of the apparatus is degraded, and cable management and maintenance is complicated. Furthermore, an overall size of the equipment increases, and design and manufacturing cost rises, resulting in higher equipment cost. In addition, power loss increases as converted power is transmitted to the jig unit through long cables, thus reducing the overall efficiency of the equipment.

In addition, secondary batteries are configured in various type, and spacing between a pair of electrodes (a positive (+) electrode and a negative (-) electrode)varies depending on each type of secondary batteries. However, the conventional charging and discharging apparatus is designed and manufactured in accordance with electrode spacing of each individual secondary battery, or is configured to require replacement of a component to accommodate such electrode spacing. Accordingly, manufacturing and operating cost of the equipment increases and process efficiency is reduced.

### Related Art Document

### Patent Document

Patent Application Publication No. 10-2013-0134431 (published on December 10, 2013)

### SUMMARY

The present disclosure is directed to providing a secondary battery charging and discharging apparatus integrated with a power supply unit which is capable of improving maintainability of the secondary battery charging and discharging apparatus, providing convenience in cable management and maintenance, achieving miniaturization of the charging and discharging apparatus, and minimizing power loss.

The present disclosure is also directed to providing a charging and discharging apparatus integrated with a power supply unit which has structural flexibility to flexibly accommodate variations in electrode spacing for various types of secondary batteries by using a single charging and discharging apparatus.

According to embodiments of the present disclosure, provided is a secondary battery charging and discharging apparatus integrated with a power supply unit, the secondary battery charging and discharging apparatus configured to perform charging and discharging for secondary battery activation or testing, and including: a jig unit configured to accommodate a plurality of secondary batteries; a rail unit disposed on the jig unit; and a power supply unit provided with a power module configured to charge and discharge the secondary batteries and a charging and discharging probe electrically connected to the power module, wherein the power supply unit is connected to the jig unit through the rail unit and is insertable into and withdrawable from the jig unit in a sliding manner.

in the secondary battery charging and discharging apparatus according to the present disclosure, the jig unit may include: a lower base frame; an upper securing frame spaced apart from the lower base frame; a lifting frame disposed between the lower base frame and the upper securing frame and configured to be vertically movable; a battery tray supported by the lifting frame, wherein the plurality of secondary batteries are mounted on the battery tray; and a lifting drive module configured to drive the lifting frame to vertically move, and the rail unit may be disposed of on the upper securing frame.

In the secondary battery charging and discharging apparatus according to the present disclosure, the lower base frame and the upper securing frame may be connected by two or more lifting guide shafts, and the lifting frame may be configured to vertically move along the lifting guide shafts between the lower base frame and the upper securing frame, when the lifting drive module operates.

In the secondary battery charging and discharging apparatus according to the present disclosure, the rail unit may be configured to include: at least two rail retainers installed upright on the upper securing frame of the jig unit and spaced apart from each other; and rail modules disposed to be opposite to each other on the respective rail retainers adjacent to each other, and configured to guide the power supply unit such that the power supply unit is insertable into and withdrawable from the jig unit in a sliding manner in a horizontal direction.

Here, each of the rail module may be configured to include: a side rail support provided with a plurality of rotating elements configured to rotate and guide and support movement of the power supply unit in the horizontal direction; and an upper retainer provided with a plurality of rotating elements, and configured to restrain movement other than predetermined movement in the horizontal direction by covering, from above, a side surface portion of a power tray included in the power supply unit.

In the secondary battery charging and discharging apparatus according to the present disclosure, the rail unit may further include a locking member installed on the upper retainer and configured to secure the power supply unit at a desired position such that the power supply unit is prevented from moving.

In the secondary battery charging and discharging apparatus according to the present disclosure, the power supply unit may further include a plate-shaped power tray disposed to be opposite to the secondary batteries mounted on the jig unit, and configured to be slidably movable along the rail unit in a horizontal direction; the charging and discharging probe may include a plurality of charging and discharging probes, and the charging and discharging probes are disposed on a first surface of the power tray that faces the secondary batteries and are configured such that two of the charging and discharging probes form a pair to correspond to each of the secondary batteries; and the power module may be mounted on a second surface of the power tray that is located opposite the first surface.

Here, the power module may be provided with a plurality of charging and discharging boards, each of the charging and discharging probes corresponding to a respective pair of charging and discharging probes and configured to perform power supply.

In the secondary battery charging and discharging apparatus according to the present disclosure, the power module may preferably include: a unit frame; a plurality of lower securing members disposed at intervals at a lower end portion of the unit frame; upper securing members disposed at an upper end portion of the unit frame and configured to correspond to the respective lower securing members; and a plurality of charging and discharging boards mounted to the unit frame and configured to be insertable into and withdrawable from the unit frame in a sliding manner through the upper securing members and the lower securing members that correspond to each other and form a pair.

Here, each of the lower securing members may be formed with a slot for the sliding insertion and withdrawal of the charging and discharging boards, and each of the upper securing members may be formed with a slot corresponding to the slot of each of the lower securing members.

In the secondary battery charging and discharging apparatus according to the present disclosure, the unit frame may further include: a main board disposed on one side of the unit frame, wherein the plurality of charging and discharging boards are simultaneously electrically connected to the main board; and a plurality of cooling fans installed at an upper portion of the unit frame, and configured to supply cooling air toward the charging and discharging boards.

In the secondary battery charging and discharging apparatus according to the present disclosure, each of the charging and discharging boards may be provided with a pair of output terminals.

Here, one of the pair of output terminals may be electrically connected through a first charging and discharging cable to one of the two charging and discharging probes corresponding to each of the charging and discharging boards, and a remaining one of the output terminals may be electrically connected through a second charging and discharging cable to a remaining one of the two charging and discharging probes.

In the secondary battery charging and discharging apparatus according to the present disclosure, the charging and discharging probe may include a plurality of charging and discharging probes configured such that two of the charging and discharging probes form a pair to correspond to each of the secondary batteries, and spacing between the two charging and discharging probes of each pair of the charging and discharging probes may be configured to be simultaneously and automatically adjusted in accordance with electrode spacing that varies depending on a type of secondary battery.

The secondary battery charging and discharging according to the present disclosure may further include a spacing adjustment unit configured to automatically synchronize and adjust the spacing between the charging and discharging probes that form a pair.

Here, the spacing adjustment unit may include: a first movable block and a second movable block configured to be movable in a direction toward or away from each other along a linear guide installed on a first surface of a power tray forming the power supply unit; and a spacing adjustment drive module driven to simultaneously move the first movable block and the second movable block toward each other or in opposite directions to each other.

In the secondary battery charging and discharging apparatus according to the present disclosure, a plurality of first charging and discharging probes may be disposed in a row at certain intervals on the first movable block, and a plurality of second charging and discharging probes may be installed on the second movable block and form a pair with corresponding ones of the first charging and discharging probes.

In the secondary battery charging and discharging apparatus according to the present disclosure, the spacing adjustment drive module may include: an actuator configured to generate rotational force for adjusting spacing; a rotation shaft configured to perform rotational motion by the actuator; a spacing adjustment shaft disposed to intersect the rotation shaft at a right angle, and configured to perform rotational motion in conjunction with the rotational motion of the rotation shaft through a power transmission element; and a motion conversion element installed in each of the first movable block and the second movable block, and configured to convert the rotational motion of the spacing adjustment shaft into linear motion.

Here, the spacing adjustment shaft may have a left-hand thread formed on one side with respect to a central portion intersecting the rotation shaft and a right-hand thread formed on an opposite side, and the motion conversion element may be a nut configured to be threadably engaged with the threads of the spacing adjustment shaft.

With a secondary battery charging and discharging apparatus integrated with a power supply unit according to the present disclosure, a power supply unit configured to perform a power conversion function for charging and discharging a secondary battery is integrated with a jig unit configured to seat and secure the secondary battery, and thus a need for providing a separate space for disposing the power supply unit may be eliminated. In addition, an installation footprint of the apparatus may significantly decrease compared with a conventional configuration in which the power supply unit is separately provided, and thus miniaturization of the charging and discharging apparatus may be effectively achieved.

In addition, the power supply unit is configured to be coupled to the jig unit in a sliding manner, thus facilitating maintenance. The power supply unit is integrated with the jig unit, a length of a charging and discharging cable that electrically connects the power supply unit and the jig unit is reduced, thus facilitating management of the charging and discharging cable and enhancing maintenance convenience. Furthermore, the reduced length of the charging and discharging cable may decrease power loss, thus enhancing power efficiency accordingly.

In addition, by adopting a configuration capable of automatically adjusting spacing between charging and discharging probes in accordance with electrode spacing that varies depending on a type of secondary battery, a single charging and discharging apparatus may be used to flexibly accommodate a secondary battery type having varying electrode spacing, compared with the conventional configuration that requires designing and manufacturing of equipment in accordance with electrode spacing of individual secondary batteries or replacement of components in accordance with such electrode spacing. Accordingly, process efficiency and equipment operational convenience may be significantly enhanced.

### BRIEF DESCRIPTION OF THE DRAWINGS

FIG. 1 is a perspective view of a secondary battery charging and discharging apparatus according to embodiments of the present disclosure.

FIG. 2 is a front view of the secondary battery charging and discharging apparatus in FIG. 1.

FIG. 3 is a side view (left side view) of the secondary battery charging and discharging apparatus in FIG. 1.

FIG. 4A and 4B are a views showing a power supply unit being inserted into and withdrawn from a jig unit in a sliding manner.

FIG. 5 is a view illustrating the jig unit separated from the secondary battery charging and discharging apparatus shown in FIGS. 1 to 3.

FIG. 6 is an enlarged view illustrating a rail unit in the secondary battery charging and discharging apparatus according to embodiments of the present disclosure.

FIGS. 7 to 9 are views illustrating the power supply unit separated from the secondary battery charging and discharging apparatus shown in FIGS. 1 to 3. FIG. 7 is a front view of the power supply unit, and FIGS. 8 and 9 are enlarged partial perspective views of the power supply unit when viewed from different angles.

FIG. 10 is an enlarged view illustrating a main portion of a power module to show a state in which a charging and discharging board is coupled.

FIG. 11 is a view illustrating a preferred embodiment of a spacing adjustment unit configured to automatically synchronize and adjust spacing between paired charging and discharging probes.

FIG. 12 is an enlarged detailed view of a main portion of the present disclosure illustrating portion 'A' in FIG. 11.

FIG. 13 is an operation state view of the present disclosure illustrating a process of adjusting the spacing between the pair of charging and discharging probes in response to driving of the spacing adjustment unit shown in FIGS. 11 and 12.

### DETAILED DESCRIPTION

Various exemplary embodiments of the present disclosure will be described in detail below.

The embodiments are provided to more fully describe the present disclosure to those skilled in the art. The following embodiments may be modified in various other forms. The scope of the present disclosure is not limited to the following embodiments. Rather, these embodiments are provided to make the present disclosure more thorough and complete and fully convey the spirit of the present disclosure.

The terminology used herein is for the purpose of describing particular embodiments and is not intended to limit the present disclosure. In addition, as used herein, singular forms may include plural forms, unless the context clearly indicates otherwise.

In the present application, terms such as “comprising/including,” “being provided with,” or “having” are intended to specify the presence of a feature, a number, a step, an operation, a component, a part, or a combination thereof of the present disclosure, but are not to be construed as precluding the possibility of the presence or addition of one or more other features, numbers, steps, operations, components, parts, or combinations thereof.

In addition, unless otherwise specified, when a component is described as being positioned "in front of," "behind," "above," or "below" another component, such description includes not only a case where the component is disposed immediately adjacent to the another component, but also a case where still another component is interposed therebetween. In addition, unless otherwise specified, when a component is described as being "connected" to another component, such description includes not only a case where the components are directly connected to each other, but also a case where the components are indirectly connected to each other.

The drawings are merely intended to facilitate understanding of the spirit of the present disclosure, and should not be construed as limiting the scope of the present disclosure. In addition, it should be noted that a relative thickness, a length, or a relative size in the drawings may be exaggerated for convenience and clarity of description.

A secondary battery charging and discharging apparatus according to embodiments of the present disclosure is an apparatus used in a charging and discharging process during a secondary battery manufacturing process. The secondary battery charging and discharging apparatus according to embodiments is designed to be suitable for mass production and is configured to simultaneously perform charging and discharging on a plurality of secondary batteries. In particular, a power supply unit configured to perform a power conversion function for charging and discharging the secondary batteries is integrated with a jig unit configured to seat and secure the secondary batteries, and is configured, as a single charging and discharging apparatus, to flexibly accommodate variations in electrode spacing for various types of secondary batteries.

For reference, the secondary battery charging and discharging process is a key operation that determines the performance and lifespan of a battery, and plays an important role in promoting initial activation of the battery and making adjustment for optimal performance of the battery. The charging and discharging process is generally referred to as a formation process, and is an important process in optimizing an active material reaction within a cell and forming a stable structure.

The secondary battery charging and discharging apparatus according to embodiments of the present disclosure will be described in detail with reference to the accompanying drawings.

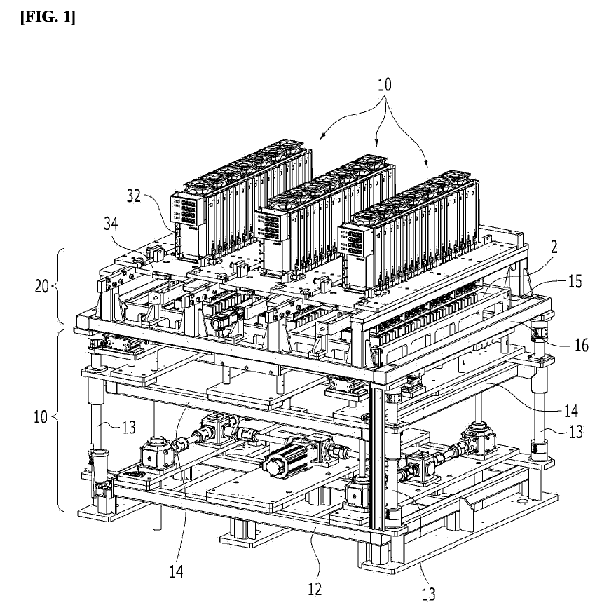

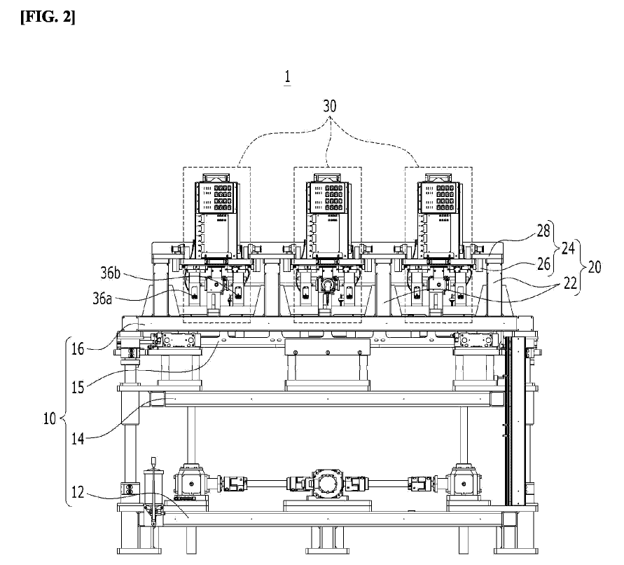

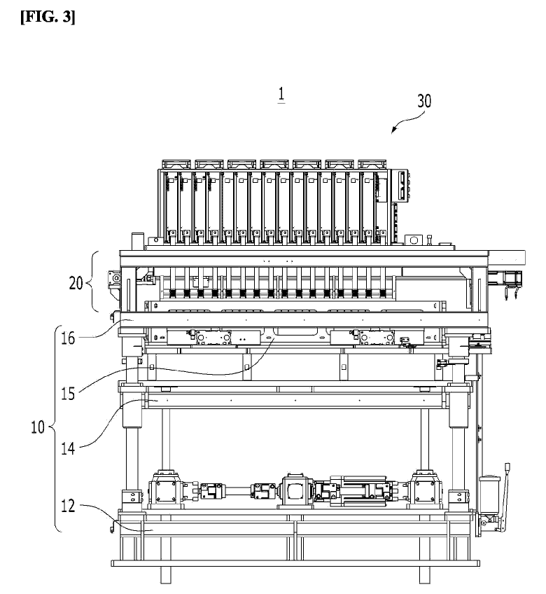

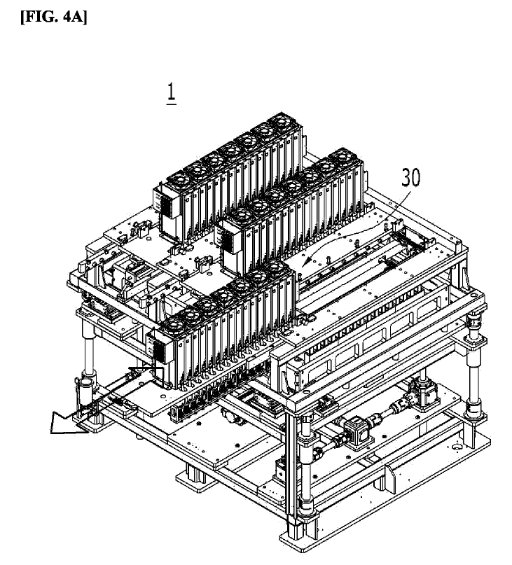

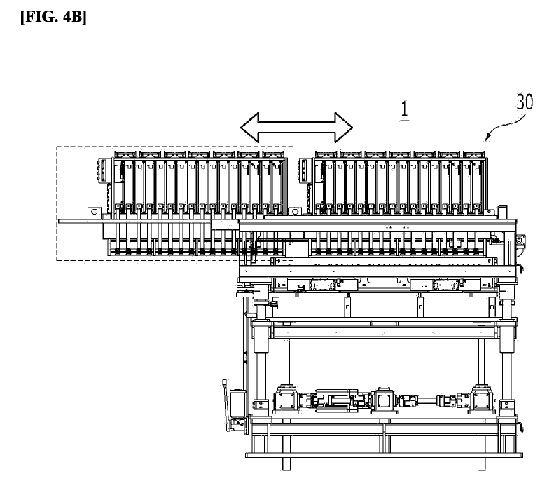

FIG. 1 is a perspective view of a secondary battery charging and discharging apparatus according to embodiments of the present disclosure. FIG. 2 is a front view of the secondary battery charging and discharging apparatus in FIG. 1. FIG. 3 is a side view (left side view) of the secondary battery charging and discharging apparatus in FIG. 1. In addition, FIG. 4A and 4B are a views showing a power supply unit being inserted into and withdrawn from a jig unit in a sliding manner. An overall configuration of the secondary battery charging and discharging apparatus according to embodiments of the present disclosure will be first described with reference to the drawings.

Referring to FIGS. 1 to 4, a secondary battery charging and discharging apparatus 1 according to embodiments is an apparatus configured to perform charging and discharging for activating or testing a secondary battery, and includes a jig unit 10, a rail unit 20, and a power supply unit 30. The jig unit 10 may be configured to accommodate a plurality of secondary batteries 2. The rail unit 20 may be disposed on the jig unit 10, and the power supply unit 30 may be integrally configured with the jig unit 10 through the rail unit 20.

The jig unit 10 may be configured to mount and secure the plurality of secondary batteries 2. The jig unit 10 may also be configured to move the plurality of secondary batteries 2 from a predetermined loading and unloading position to a charging and discharging position, or vice versa. The power supply unit 30 is configured to perform charging and discharging of the secondary batteries 2 secured at the charging and discharging position, and may include various charging and discharging elements such as a power module 32 and charging and discharging probes 36a and 36b.

Loading and unloading of the secondary batteries 2 onto and from the jig unit 10 may be performed by using a dedicated loading and unloading robot or by manual operation. The power supply unit 30 may be coupled to the jig unit 10 through the rail unit 20 disposed on the jig unit 10 and may be slidably inserted into and withdrawn from the jig unit 10 (see FIG. 4A and 4B). Accordingly, with the secondary battery charging and discharging apparatus 1 according to embodiments, maintenance or replacement of components of the power supply unit 30 that includes the power module 32 and the charging and discharging probes 36a and 36b may be performed very efficiently.

The configuration of the secondary battery charging and discharging apparatus according to embodiments will be described in more detail for each part.

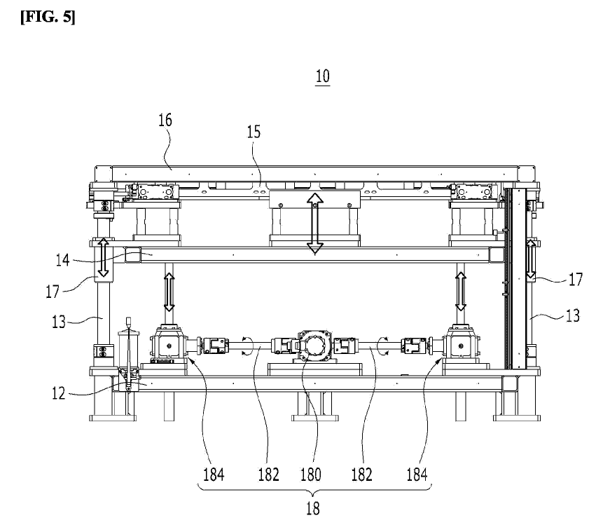

FIG. 5 is a view illustrating the jig unit separated from the secondary battery charging and discharging apparatus shown in FIGS. 1 to 3 described above, and the configuration of the jig unit will be first described in detail with reference to FIG. 5.

Referring to FIG. 5, the jig unit 10 includes a lower base frame 12 and an upper securing frame 16 which are spaced apart from each other. A lifting frame 14 may be disposed to be vertically movable between the two frames 12 and 16. A battery tray 15 configured to mount and secure the plurality of secondary batteries 2 may be seated and secured on the lifting frame 14. For example, to perform more efficient loading and unloading of the secondary batteries 2, the battery tray 15 may be configured to be detachable from the lifting frame 14.

The lifting frame 14 may be driven, by a lifting drive module 18, to move in a vertical direction as shown in FIG. 5. Accordingly, the plurality of secondary batteries 2 may be mounted on the battery tray 15 at a predetermined initial loading position, and then may move to a predetermined charging and discharging position in response to an upward movement of the lifting frame 14 driven by the lifting drive module 18. In addition, when the charging and discharging process is completed, the plurality of secondary batteries 2 may move to a predetermined unloading position (or initial loading position) in response to a downward movement of the lifting frame 14.

In embodiments, the lower base frame 12 and the upper securing frame 16 may be interconnected through a lifting guide shaft 13 disposed vertically as shown in FIG. 5. Two or more lifting guide shafts 13 may be formed. A tubular lifting member 17 is mounted on each of the lifting guide shafts 13 and is configured to be slidable along the corresponding lifting guide shaft 13. The lifting frame 14 may be connected to the lifting guide shaft 13 by means of the lifting member 17 and is configured to be vertically movable.

Accordingly, when the lifting drive module 18 is driven in accordance with a set control sequence, the lifting frame 14 may be safely and stably moved vertically along a determined lifting path by the lifting guide shafts 13. As a result, the plurality of secondary batteries 2 may stably move from the loading position to the charging and discharging position or vice versa without wobbling, and accordingly, accuracy and reliability of the charging and discharging process may be enhanced.

The lifting drive module 18 may employ, for example, a motor-based drive mechanism including a motor 180 configured to generate rotational force, a power transmission shaft 182 configured to perform rotational motion by the rotational force of the motor 180, and a conversion element 184, such a lead screw, a ball screw, or a cam, configured to convert the rotational motion of the power transmission shaft 182 into linear motion. Of course, the lifting drive module 18 is not limited thereto, and a cylinder-based drive mechanism including a hydraulic or pneumatic cylinder may alternatively be employed.

That is, the drive mechanism of the lifting drive module 18 that is employed in embodiments may be appropriately selected from among known lifting drive mechanisms depending on a design objective or usage environment of the secondary battery charging and discharging apparatus. More specifically, each drive mechanism may be configured to achieve optimal performance by taking into account controllability, operational efficiency, movement accuracy, speed, and, ease of maintenance of the lifting drive module 18.

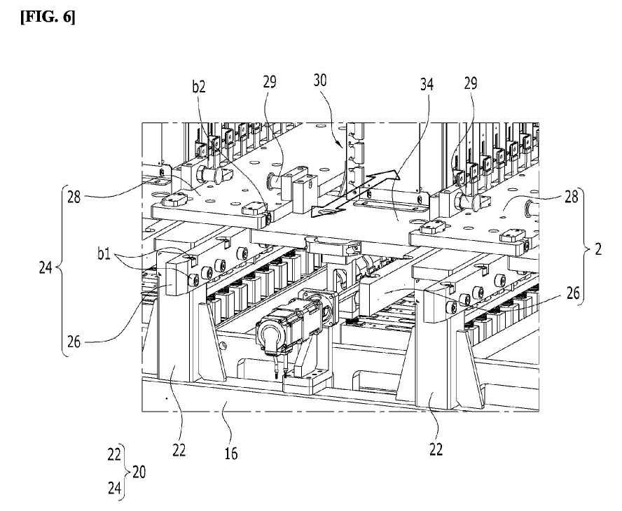

FIG. 6 is an enlarged view illustrating a rail unit in the secondary battery charging and discharging apparatus according to embodiments of the present disclosure.

Referring to FIG. 6, the rail unit 20 may be disposed on the jig unit 10. Preferably, the rail unit 20 may be disposed on the upper securing frame 16 of the jig unit 10 and guide the sliding insertion and withdrawal of the power supply unit 30 into and from the jig unit 10. As an example, the rail unit 20 may include a pair of rail retainers 22 and a rail module 24 which is disposed opposite each of the rail retainers 22 and guides the insertion and withdrawal of the power supply unit 30.

The rail retainers 22 may include at least two structures that are installed upright on the upper securing frame 16 of the jig unit 10 and spaced apart from each other. The rail modules 24 may be disposed to be opposite to each other on the respective rail retainers 22, which are adjacent to each other, and may serve to guide the power supply unit 30 such that the power supply unit 30 may be stably inserted into and withdrawn from the jig unit 10 in a sliding manner in a horizontal direction without wobbling.

The rail module 24 may include a side rail support 26 and an upper retainer 28. The side rail support 26 may be provided with a plurality of rotating elements b1, such as a bearing, configured to rotate in a secured state and precisely guide and support movement of the power supply unit 30 in the horizontal direction (an arrow direction as shown in FIG. 6). The upper retainer 28 serves to restrain movement other than predetermined movement in the horizontal direction by covering, from above, a portion of a side surface of a power tray 34 included in the power supply unit 30.

The upper retainer 28 may also be provided with a plurality of rotating elements b2 configured to rotate in a secured state and precisely guide movement of the power tray 34. In addition, a locking member 29 may be installed on the upper retainer 28 and reliably secures the power supply unit 30 which is inserted and withdrawn in a sliding manner at a desired position. The locking member 29 may have a structure such as, for example, an index plunger. Of course, the locking member 29 may be modified into various other forms depending on a design objective or usage environment of the apparatus.

For reference, in a preferred embodiment of the present disclosure, FIGS. 1 to 3 described above illustrate a configuration in which three power supply units 30 having an identical configuration are installed to be insertable into and withdrawable from a single jig unit 10 through three pairs of the rail units 20. However, the number of the power supply units 30 is not limited to three, and it should be noted that the number of power supply units 30 may be flexibly adjusted depending on required specifications, processing capacity, usage environment, or the like of the apparatus.

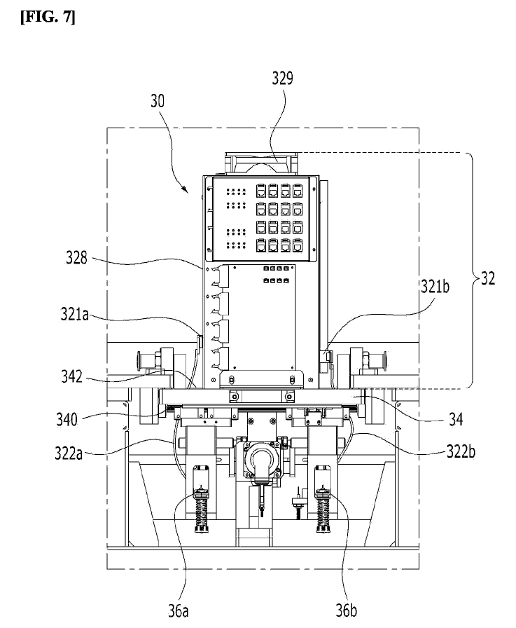

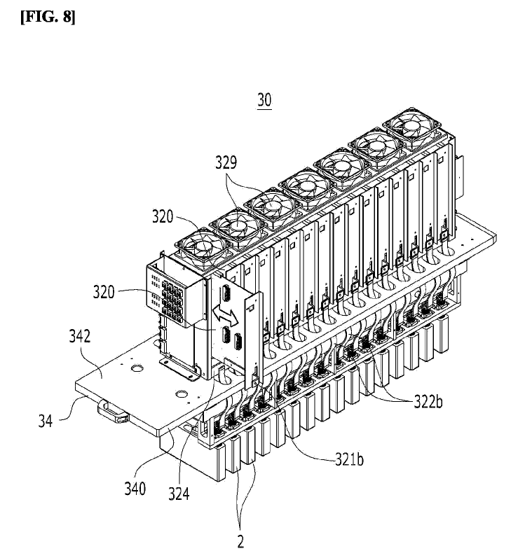

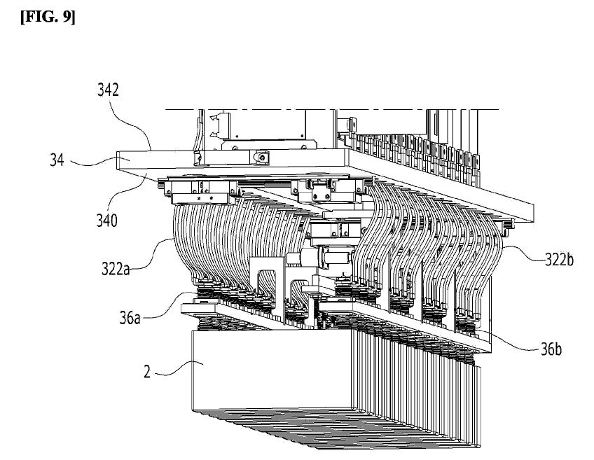

FIGS. 7 to 9 are views illustrating the power supply unit separated from the secondary battery charging and discharging apparatus shown in FIGS. 1 to 3. FIG. 7 is a front view of the power supply unit, and FIGS. 8 and 9 are enlarged partial perspective views of the power supply unit when viewed from different angles.

Referring to FIGS. 7 to 9, the power supply unit 30 includes the power tray 34 configured as a plate having a rectangular planar shape. The power tray 34 may be configured to be movable in the horizontal direction along the rail unit 20 described above. A plurality of pairs of the charging and discharging probes 36a and 36b may be disposed on a first surface 340 of the power tray 34 that faces the secondary batteries 2(a lower surface of the power tray 34 in the drawings), and the power module 32 may be mounted on an opposite second surface 342 (an upper surface of the power tray 34 in the drawings).

The plurality of pairs of the charging and discharging probes 36a and 36b may be disposed on the first surface 340 such that two of the charging and discharging probes 36a and 36b may form a pair and correspond to each of the secondary batteries 2. In addition, the power module 32 may be provided with a plurality of charging and discharging boards 32, and each of the charging and discharging boards 32 corresponds to one pair of the charging and discharging probes 36a and 36b and independently supplies power. Accordingly, individual charging and discharging control may be performed for each of the secondary batteries 2, and only the charging and discharging boards 320 may be individually replaced or upgraded during maintenance.

Each of the charging and discharging boards 320 forming the power module 32 may be provided with a pair of output terminals (a positive (+) terminal and a negative (-) terminal). One of the pair of output terminals 321a and 321b may be electrically connected through a first charging and discharging cable 322a to one of the two charging and discharging probes 36a and 36b corresponding to each of the charging and discharging boards 320. In addition, a remaining one of the output terminals 321a and 321b may be electrically connected through a second charging and discharging cable 322b to a remaining one of the two charging and discharging probes 36a and 36b.

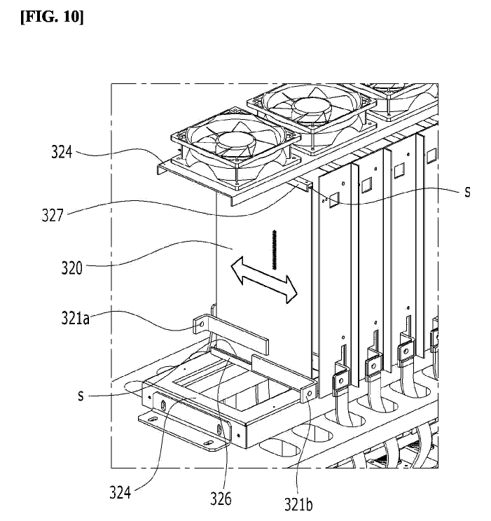

FIG. 10 is an enlarged view illustrating a main portion of a power module to show a state in which a charging and discharging board is coupled.

Referring to FIG. 10 and FIG. 8 described above, the power module 32 includes a unit frame 324 and a plurality of lower securing members 326 disposed at intervals at a lower end portion of the unit frame 324. The power module 32 further includes: upper securing members 327 disposed at an upper end portion of the unit frame 324 and configured to correspond to the respective lower securing members 326; and a plurality of the charging and discharging boards 320 mounted and secured to the unit frame 324 through corresponding pairs of the upper securing members 327 and the lower securing members 326.

Each of the lower securing members 326 may have slots s formed continuously in a lengthwise direction of the lower securing members 326 and configured to allow sliding insertion and withdrawal of the charging and discharging boards 320, and corresponding slots s may also be formed in each of the upper securing members 327. Accordingly, each of the charging and discharging boards 320 may be detachably mounted to the unit frame 324 in a lateral sliding insertion and withdrawal manner through a corresponding pair of the lower and upper securing members 326 and 327, as shown in FIG. 8.

With this configuration, only the charging and discharging board 320 that requires maintenance may be individually and easily withdrawn. Accordingly, ease of replacement or upgrade of the charging and discharging board 320 may be ensured, and as a result, maintenance efficiency may be significantly enhanced. In addition, the ease of replacement or upgrade of the charging and discharging board 320 may reduce maintenance time and enable rapid response to a malfunction.

In embodiments, the power module 32 may include a main board 328 and a cooling fan 329 (see FIGS. 7 and 8). The main board 328 may be disposed on one side surface of the unit frame 324, and may be provided with a plurality of connectors (not illustrated) configured to electrically connect the plurality of charging and discharging boards 32 simultaneously. A plurality of the cooling fans 329 may be installed at an upper portion of the unit frame 324, and may be configured to efficiently supply cooling air toward the plurality of charging and discharging boards 32.

As described above, the plurality of pairs of the charging and discharging probes 36a and 36b may be configured such that two of the charging and discharging probes 36a and 36b may form a pair and correspond to each of the secondary batteries 2. Each of the secondary batteries 2 includes a positive (+) terminal and a negative (−) terminal for charging and discharging, and spacing between the two terminals varies depending on a type or design specifications of secondary batteries. Accordingly, in order to accommodate various types of secondary batteries in a single charging and discharging apparatus, a technical mechanism capable of flexibly accommodating variations in electrode spacing is required.

The secondary battery charging and discharging apparatus 1 according to embodiments may include a mechanism for automatically adjusting the spacing between the two charging and discharging probes 36a and 36b of each pair of the charging and discharging probes, in accordance with electrode spacing that varies depending on a type of secondary battery. More specifically, the secondary battery charging and discharging apparatus 1 may include a spacing adjustment unit 40 configured to automatically synchronize and adjust spacing between the paired charging and discharging probes 36a and 36b. The spacing adjustment unit 40 may be configured to flexibly accommodate various types of secondary batteries.

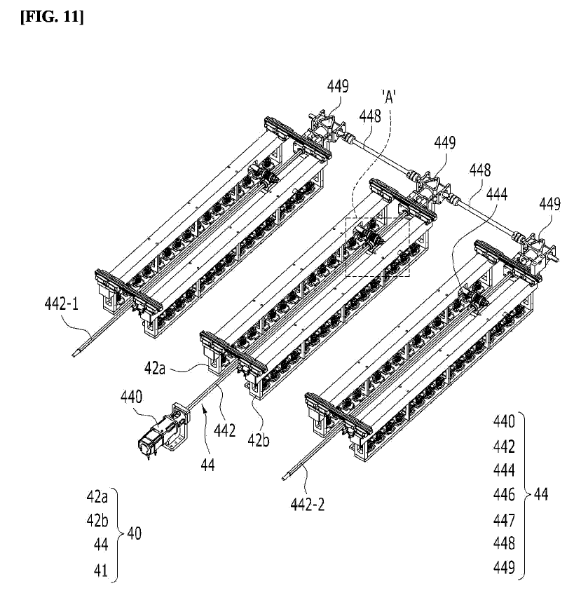

A preferred embodiment of a spacing adjustment unit will be described below in detail with reference to FIGS. 11 to 13.

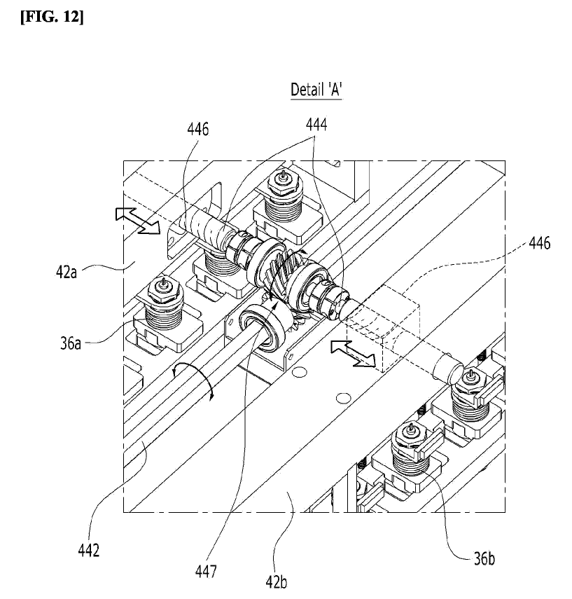

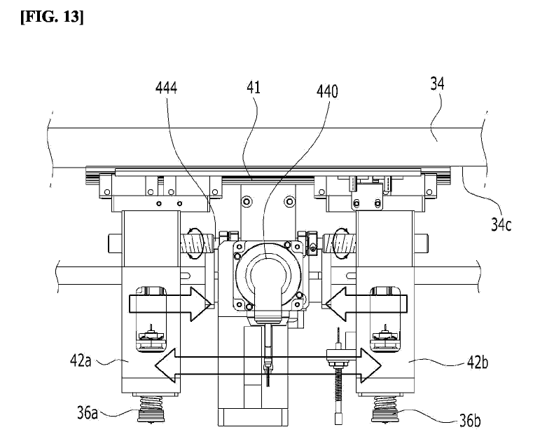

FIG. 11 is a view illustrating a preferred embodiment of a spacing adjustment unit configured to automatically synchronize and adjust spacing between paired charging and discharging probes, and shows a mechanism for simultaneously adjusting the spacing between each pair of charging and discharging probes that form three power supply units by using a single actuator (e.g., a stepper motor). In addition, FIG. 12 is an enlarged detailed view of a main portion of the present disclosure illustrating portion 'A' in FIG. 11. FIG. 13 is an operation state view of the present disclosure illustrating a process of adjusting the spacing between the pair of charging and discharging probes in response to driving of the spacing adjustment unit.

Referring to FIGS. 11 to 13, by way of a preferred example, the spacing adjustment unit 40 according to embodiments includes: a first movable block 42a and a second movable block 42b provided in each of the power supply units 30 (each of the power supply units 30 provided in three rows as shown in the drawings); and a spacing adjustment drive module 44 configured to drive the first movable block 42a and the second movable block 42b provided in each of the power supply units 30 such that the first movable block 42a and the second movable block 42b move simultaneously toward each other or in opposite directions to each other.

The first movable block 42a and the second movable block 42b may be disposed on the first surface 340 of the power tray 34 forming each of the power supply units 30 and configured to be movable in a certain direction (a lateral direction as shown in FIG. 13) by means of a linear guide 41. More specifically, the first movable block 42a and the second movable block 42b may be mounted to be movable in a direction toward or away from each other along the linear guide 41 installed on the first surface 340 of the power tray 34 forming each of the power supply units 30.

In embodiments, a plurality of the first charging and discharging probes 36a may be disposed on the first movable block 42a at certain intervals along a direction intersecting the certain direction at a right angle (a lengthwise direction of the power supply unit 30 as shown in FIG. 11). In a corresponding manner, a plurality of the second charging and discharging probes 36b may be disposed on the second movable block 42b and configured to be opposite to the respective first charging and discharging probes 36a of the first movable blocks 42a and paired with the same in a one-to-one correspondence.

With this configuration, when the spacing adjustment unit 40 is driven, the first movable block 42a and the second movable block 42b may move simultaneously along the linear guide 41 in a direction toward or away from each other. Accordingly, the spacing between each pair of the charging and discharging probes 36a and 36b may be adjusted in accordance with electrode spacing that varies depending on a type of secondary battery. That is, the spacing between each pair of the charging and discharging probes 36a and 36b may be flexibly adjusted in accordance with electrode spacing that varies depending on a type of secondary battery.

The spacing adjustment drive module 44 may include an actuator 440, a rotation shaft 442, a spacing adjustment shaft 444, and a motion conversion element 446. The actuator 440 may generate rotational force for adjusting spacing. The actuator 440 may be, for example, a stepper motor. The rotation shaft 442 may receive the rotational force generated by the actuator 440 and perform rotational motion. The spacing adjustment shaft 444 may be disposed to intersect the rotation shaft 442 at a right angle and configured to perform rotational motion in conjunction with the rotational motion of the rotation shaft 442.

The spacing adjustment shaft 444 may be connected to the rotation shaft 442 so as to transmit power to the rotation shaft 442 by means of a power transmission element 447 disposed therebetween. The power transmission element 447 may be, for example, a worm gear including a worm and a worm wheel, but is not limited thereto. In addition, each of the first movable block 42a and the second movable block 42b may be provided with the motion conversion element 446 configured to convert the rotational motion of the spacing adjustment shaft 444 that has been generated by the rotation shaft 442 into linear motion.

As an example, the spacing adjustment shaft 444 may be configured to have threads formed on opposite sides of the spacing adjustment shaft 444 with respect to a central portion intersecting the rotation shaft 442. For example, the spacing adjustment shaft 444 may have a left-hand thread formed on one side with respect to the central portion and a right-hand thread formed on an opposite side. In this case, the motion conversion element 446 may be a nut-shaped block configured to be threadably engaged with the threads of the spacing adjustment shaft 444.

With this configuration, as illustrated in FIG. 13, when the spacing adjustment shaft 444 rotates, the first movable block 42a and the second movable block 42b are simultaneously moved in a direction toward or away from each other (see an arrow direction in FIG. 13) by the nut-shaped motion conversion element 446. As a result, precise adjustment of the spacing between each pair of the charging and discharging probes 36a and 36b may be achieved in accordance with electrode spacing that varies depending on a type of secondary battery.

The spacing adjustment unit 40 may be configured such that a single actuator 440 simultaneously moves the first movable block 42a and the second movable block 42b disposed in each of the power supply units 30 by an identical distance. This configuration may be implemented through a mechanism in which, as in an example shown in FIG. 11, a single rotation shaft 442 is disposed at each of the power supply units 30; one of the rotation shafts 442 is directly connected to the actuator 440; and remaining rotation shafts 442-1 and 442-2 are operatively connected to the rotation shaft 442 connected to the actuator 440 through an intermediate shaft 448 and a gearbox 449.

Of course, the present disclosure is not limited to a configuration in which a single actuator simultaneously moves, by an equal distance, the first and second movable blocks disposed in all power supply units. This mechanism may be effective in terms of power efficiency because driving force of a single actuator is transmitted to pairs of charging and discharging probes of all power supply units. However, in some cases, an actuator may be independently connected to each rotation shaft disposed at the corresponding power supply unit.

When an actuator is independently connected to each rotation shaft in this manner, spacing between a pair of charging and discharging probes may be individually adjusted for the corresponding power supply unit. In this case, charging and discharging processes for various types of secondary batteries may be performed in a single process by using a single charging and discharging apparatus. This configuration may be useful in a case where flexible spacing adjustment is required depending on a particular secondary battery type or process condition.

A conventional charging and discharging apparatus used in a secondary battery manufacturing process has a structure in which a power supply unit configured to perform power conversion for charging and discharging a secondary battery includes a charging and discharging probe such that the power supply unit is separated from a jig unit on which the secondary battery is seated and secured, and is electrically connected to the jig unit through a separate cable. This structure requires a separate space for disposing the power supply unit, and thus an overall installation footprint of the equipment increases.

In the secondary battery charging and discharging apparatus according to embodiments, a power supply unit configured to perform a power conversion function is integrally formed with a jig unit configured to seat and secure a secondary battery. Accordingly, there is no need to provide a separate space for disposing the power supply unit, and an installation footprint of the apparatus may significantly decrease compared with a conventional separate-type configuration. As a result, miniaturization of the charging and discharging apparatus may be effectively achieved.

In addition, the power supply unit is designed to be coupled to the jig unit in a sliding manner, thus facilitating maintenance. Since the power supply unit is integrated with the jig unit, a length of a charging and discharging cable that electrically connects the power supply unit and the jig unit is reduced, thus facilitating management of the charging and discharging cable and enhancing maintenance convenience. Furthermore, the reduced length of the charging and discharging cable decrease power loss, thus enhancing power efficiency.

The secondary battery charging and discharging apparatus according to embodiments further includes a configuration capable of automatically adjusting spacing between charging and discharging probes in accordance with electrode spacing that varies depending on a type of secondary battery. This eliminates a cumbersome process of designing and manufacturing equipment in accordance with electrode spacing of individual secondary batteries or replacing components to accommodate such electrode spacing as in the related art, and enables a single charging and discharging apparatus to flexibly accommodate a secondary battery type having varying electrode spacing.

The above description is merely an exemplary description of the technical spirit of the present disclosure, and it will be apparent to those skilled in the art that various modifications and variations may be made without departing from the principles of the present disclosure.

Therefore, the embodiments disclosed herein are intended not to limit but to describe the technical spirit of the present disclosure, and the scope of the technical spirit of the present disclosure is not limited by the embodiments. The protection scope of the present disclosure should be construed in accordance with the following claims, and all the technical spirit within the scope of the equivalents thereof should be construed as being included within the scope of rights of the present disclosure.

What is claimed is:

1. A secondary battery charging and discharging apparatus integrated with a power supply unit, the secondary battery charging and discharging apparatus configured to perform charging and discharging for secondary battery activation or testing, and comprising:
a jig unit configured to accommodate a plurality of secondary batteries;
a rail unit disposed on the jig unit; and
a power supply unit provided with a power module configured to charge and discharge the secondary batteries and a charging and discharging probe electrically connected to the power module,
wherein the power supply unit is connected to the jig unit through the rail unit and is insertable into and withdrawable from the jig unit in a sliding manner.

2. The secondary battery charging and discharging apparatus of claim 1, wherein the jig unit comprises:
a lower base frame;
an upper securing frame spaced apart from the lower base frame;
a lifting frame disposed between the lower base frame and the upper securing frame and configured to be vertically movable;
a battery tray supported by the lifting frame, wherein the plurality of secondary batteries are mounted on the battery tray; and
a lifting drive module configured to drive the lifting frame to vertically move,
wherein the lower base frame and the upper securing frame are connected by two or more lifting guide shafts, and
when the lifting drive module operates, the lifting frame vertically moves along the lifting guide shafts between the lower base frame and the upper securing frame.

3. The secondary battery charging and discharging apparatus of claim 1, wherein the rail unit comprises:
at least two rail retainers installed upright on the upper securing frame of the jig unit and spaced apart from each other; and
rail modules disposed to be opposite to each other on the respective rail retainers adjacent to each other, and configured to guide the power supply unit such that the power supply unit is insertable into and withdrawable from the jig unit in a sliding manner in a horizontal direction,
wherein each of the rail module comprises:
a side rail support provided with a plurality of rotating elements configured to rotate and guide and support movement of the power supply unit in the horizontal direction; and
an upper retainer provided with a plurality of rotating elements, and configured to restrain movement other than predetermined movement in the horizontal direction by covering, from above, a side surface portion of a power tray comprised in the power supply unit.

4. The secondary battery charging and discharging apparatus of claim 3, wherein the rail unit further comprises a locking member installed on the upper retainer and configured to secure the power supply unit at a desired position such that the power supply unit is prevented from moving.

5. The secondary battery charging and discharging apparatus of claim 1, wherein:
the power supply unit further comprises a plate-shaped power tray disposed to be opposite to the secondary batteries mounted on the jig unit, and configured to be slidably movable along the rail unit in a horizontal direction,
the charging and discharging probe comprises a plurality of charging and discharging probes, and the charging and discharging probes are disposed on a first surface of the power tray that faces the secondary batteries and are configured such that two of the charging and discharging probes form a pair to correspond to each of the secondary batteries,
the power module is mounted on a second surface of the power tray that is located opposite the first surface, and
the power module is provided with a plurality of charging and discharging boards, each of the charging and discharging probes corresponding to a respective pair of charging and discharging probes and configured to perform power supply.

6. The secondary battery charging and discharging apparatus of claim 1, wherein the power module comprises:
a unit frame;
a plurality of lower securing members disposed at intervals at a lower end portion of the unit frame;
upper securing members disposed at an upper end portion of the unit frame and configured to correspond to the respective lower securing members; and
a plurality of charging and discharging boards mounted to the unit frame and configured to be insertable into and withdrawable from the unit frame in a sliding manner through the upper securing members and the lower securing members that correspond to each other and form a pair,
wherein each of the lower securing members is formed with a slot for the sliding insertion and withdrawal of the charging and discharging boards, and
each of the upper securing members is formed with a slot corresponding to the slot of each of the lower securing members.

7. The secondary battery charging and discharging apparatus of claim 1, wherein:
the charging and discharging probe comprises a plurality of charging and discharging probes configured such that two of the charging and discharging probes form a pair to correspond to each of the secondary batteries, and
spacing between the two charging and discharging probes of each pair of the charging and discharging probes is configured to be simultaneously and automatically adjusted in accordance with electrode spacing that varies depending on a type of secondary battery.

8. The secondary battery charging and discharging apparatus of claim 7, further comprising a spacing adjustment unit configured to automatically synchronize and adjust the spacing between the charging and discharging probes that form a pair.

9. The secondary battery charging and discharging apparatus of claim 8, wherein the spacing adjustment unit comprises:
a first movable block and a second movable block configured to be movable in a direction toward or away from each other along a linear guide installed on a first surface of a power tray forming the power supply unit; and
a spacing adjustment drive module driven to simultaneously move the first movable block and the second movable block toward each other or in opposite directions to each other,
wherein a plurality of first charging and discharging probes are disposed in a row at certain intervals on the first movable block, and
a plurality of second charging and discharging probes are installed on the second movable block and form a pair with corresponding ones of the first charging and discharging probes.

10. The secondary battery charging and discharging apparatus of claim 9, wherein the spacing adjustment drive module comprises:
an actuator configured to generate rotational force for adjusting spacing;
a rotation shaft configured to perform rotational motion by the actuator;
a spacing adjustment shaft disposed to intersect the rotation shaft at a right angle, and configured to perform rotational motion in conjunction with the rotational motion of the rotation shaft through a power transmission element; and
a motion conversion element installed in each of the first movable block and the second movable block, and configured to convert the rotational motion of the spacing adjustment shaft into linear motion.
